(19) United States
(12) Patent Application Publication
(10) Pub. No.: US 2025/0254959 A1
(43) Pub. Date: Aug. 7, 2025

(54) Semiconductor Device and Method of Producing a Semiconductor Device

(71) Applicant: Infineon Technologies Austria AG, Villach (AT)

(72) Inventors: Timothy Henson, Mount Shasta, CA (US); Oliver Blank, Villach (AT)

(21) Appl. No.: 18/434,118

(22) Filed: Feb. 6, 2024

(51) Int. Cl. H01L 29/40; H01L 29/66; H01L 29/78

(52) U.S. Cl. CPC H10D 64/118; H10D 30/0297; H10D 30/668; H10D 64/01; H10D 64/117

(57) ABSTRACT

A semiconductor device includes transistor cells formed in a semiconductor substrate and electrically coupled in parallel to form a power transistor. The transistor cells include trenches extending in a vertical direction from a first main surface of the semiconductor substrate into the semiconductor substrate. The trenches include: a gate electrode; a field electrode below the gate electrode; and at least one dielectric material separating the gate electrode and the field electrode from one another and from the semiconductor substrate. The at least one dielectric material is thicker between the field electrode and a bottom of the trenches than between the field electrode and each sidewall of the trenches. Each trench has a tapered width that decreases over a depth of the trench in the vertical direction. A method of producing the semiconductor device is also described.

### BACKGROUND

DC-DC power conversion for servers, high performance computing (HPC), and artificial intelligence (AI) demand higher efficiency and higher density. As frequencies increase, the figure-of-merit FOMoss=Rdson*Qoss becomes a dominant power loss mechanism, where Rdson is on-resistance and Qoss is output charge. Some conventional power semiconductor devices used in DC-DC power conversion systems utilize a dual polysilicon field plate design where the field plate is used to fully compensate the drift region. For these devices, FOMoss is reduced through Rdson reduction. These devices have been optimized for low Rdson over several generations of geometry shrink, making further reductions in FOMoss difficult. Single polysilicon trench devices with a trench bottom oxide have an R*AA (on-resistance times active area) figure of merit that is too high for modern space constrained high performance applications. Monolithic devices for high frequency DCDC power conversion are not capable of vertical power flow like vertical trench MOSFETs (metal-oxide-semiconductor field-effect transistors).

Thus, there is a need for an improved semiconductor device design optimized for DC-DC power conversion systems.

### SUMMARY

According to an embodiment of a semiconductor device, the semiconductor device comprises: a semiconductor substrate; and a plurality of transistor cells formed in the semiconductor substrate and electrically coupled in parallel to form a power transistor, wherein the plurality of transistor cells comprises a plurality of trenches extending in a vertical direction from a first main surface of the semiconductor substrate into the semiconductor substrate, wherein each trench of the plurality of trenches comprises: a gate electrode; a field electrode below the gate electrode; and at least one dielectric material separating the gate electrode and the field electrode from one another and from the semiconductor substrate, wherein the at least one dielectric material is thicker between the field electrode and a bottom of the trenches than between the field electrode and each sidewall of the trenches, wherein each trench has a tapered width that decreases over a depth of the trench in the vertical direction.

According to an embodiment of a method of producing a semiconductor device, the method comprises: forming a plurality of transistor cells in a semiconductor substrate; and electrically coupling the plurality of transistor cells in parallel to form a power transistor, wherein forming the plurality of transistor cells comprises: etching a plurality of trenches into a first main surface of the semiconductor substrate and extending in a vertical direction into the semiconductor substrate; and in each trench, forming a gate electrode, a field electrode below the gate electrode, and at least one dielectric material that separates the gate electrode and the field electrode from one another and from the semiconductor substrate, wherein the at least one dielectric material is thicker between the field electrode and a bottom of the trenches than between the field electrode and each sidewall of the trenches, wherein each trench has a tapered width that decreases over a depth of the trench in the vertical direction.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1A illustrates a partial top plan view of a semiconductor device in a region of several adjacent transistor cells formed in a semiconductor substrate.

FIG. 1B illustrates a cross-sectional view of the semiconductor device take along the line labelled A-A′ in FIG. 1A.

FIG. 2 illustrates a cross-sectional view of the semiconductor device take along the line labelled A-A′ in FIG. 1A, according to another embodiment.

FIGS. 3A through 3F illustrate a partial cross-sectional view between two (2) adjacent trenches of the semiconductor device during different stages of production, according to an embodiment.

### DETAILED DESCRIPTION

The embodiments described herein provide a semiconductor device optimized for DC-DC power conversion systems, and a method of producing the semiconductor device. A thick dielectric region is provided under the field electrode (plate) of the power transistor cells to significantly reduce FOMoss. The thick dielectric region is thicker than the field oxide that laterally surrounds the field electrode, e.g., 1.5 to 10 times thicker. The field electrode may extend to a shallower depth in the semiconductor substrate compared to a conventional device that does not have the thick dielectric region.

The field oxide surrounding the field electrode may be thinner or thicker than in a conventional device, to optimize the Rdson-Qoss trade-off. The epitaxial doping may be reduced compared to a conventional device to reduce Qoss. The thick dielectric region, trench depth, and field electrode depth may be optimized.

The new design may be based on a stripe dual polysilicon structure, where the field electrode is below a gate electrode in the same trench and the thick dielectric region is below the field electrode. However, the new design can also be applied to a needle trench cell or a stripe device design that uses a gate trench separated from the field electrode trench. In this case, the gate trench may or may not contain the thick dielectric region below the gate electrode.

The thick dielectric region provides several benefits in a power MOSFET device. First, the thick dielectric region partially shields the field electrode from drain potential, resulting in less change in the local field electrode voltage when the drain voltage is switched. Second, the thick dielectric region provides some dielectric RESURF (reduced surface field) to enable higher epitaxial doping and lower Rdson than a simple trench device. Third, the thick dielectric region introduces beneficial crystalline stress to the drift region, increasing carrier (e.g., electron) mobility and reducing Rdson. Fourth, the output capacitance is reduced since the source-drain capacitance of the field electrode is reduced.

Described next with reference to the figures are embodiments of the semiconductor device and a method of producing the semiconductor device.

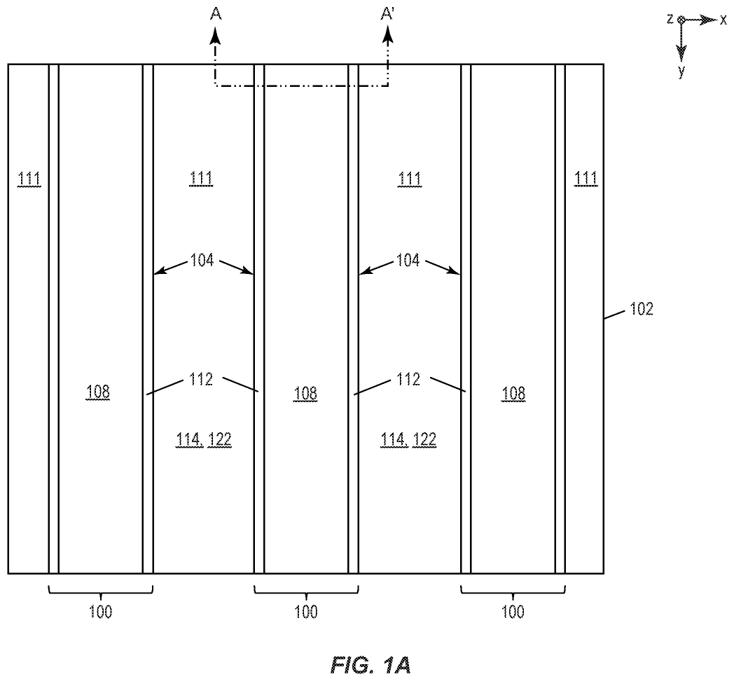

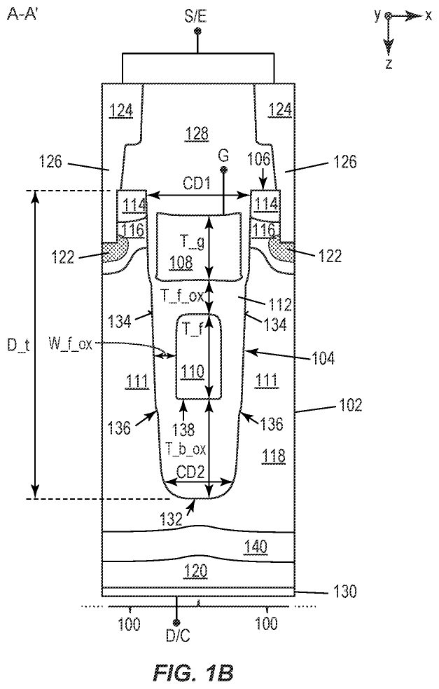

FIG. 1A illustrates a partial top plan view of the semiconductor device in a region of several adjacent transistor cells 100 formed in a semiconductor substrate 102. FIG. 1B illustrates a cross-sectional view of the semiconductor device take along the line labelled A-A′ in FIG. 1A.

The transistor cells 100 are electrically coupled in parallel to form a power transistor such as a vertical power MOSFET (metal-oxide-semiconductor field-effect transistor), where the transistor cells 100 have the same or similar construction. In general, the semiconductor device may have tens, hundreds, thousands, or even more transistors cells 100.

The semiconductor substrate 102 in which the transistor cells 100 are formed comprises one or more semiconductor materials that are used to form a power semiconductor device such as, e.g., a Si or SiC power MOSFET. For example, the semiconductor substrate 102 may comprise Si, silicon carbide (SiC), germanium (Ge), silicon germanium (SiGe), gallium nitride (GaN), gallium arsenide (GaAs), and the like. The semiconductor body 100 may include one or more epitaxial layers.

The transistor cells 100 formed in the semiconductor substrate 102 include trenches 104 that extend in a vertical direction (z direction in FIGS. 1A and 1B) from a first main surface 106 of the semiconductor substrate 102 into the semiconductor substrate 102. In FIG. 1A, the trenches 104 are stripe-shape trenches. The term ‘stripe-shape’ as used herein means a structure having a longest linear dimension in a direction (y direction in FIGS. 1A and 1B) generally perpendicular to the depth-wise direction (z direction in FIGS. 1A and 1B) of the semiconductor substrate 102.

Each trench 104 includes a gate electrode 108, a field electrode 110 below the gate electrode 108, and at least one dielectric material (such as a single dielectric material or a material stack) 112 separating the gate electrode 108 and the field electrode 110 from one another and from the semiconductor substrate 102. Each transistor cell 100 further includes a source region 114 of a first conductivity type and a body region 116 of a second conductivity type opposite the first conductivity type. The source region 114 of each transistor cell 100 is separated from a (common) drift region 118 of the first conductivity type by the corresponding body region 116. In the case of a vertical power transistor, a drain region 120 is disposed at the backside of the semiconductor substrate 102.

The first conductivity is n-type and the second conductivity type is p-type for an n-channel device formed by the transistor cells 100, whereas the first conductivity is p-type and the second conductivity type is n-type for a p-channel device formed by the transistor cells 100. For either an n-channel device or a p-channel device, the source region 114 and the body region 116 form part of a transistor cell 100 and the transistor cells 100 are electrically connected in parallel between source(S) and drain (D) terminals of the semiconductor device to form a power transistor.

The body regions 116 of the transistor cells 100 may include a body contact region 122 of the second conductivity type. The body contact region 122 has a higher doping concentration than the body regions 116, to provide an ohmic connection with a source/emitter metallization 124 through a contact structure 126 such as electrically conductive vias that extends through an interlayer dielectric 128 that separates the source metallization 124 from the semiconductor substrate 102. The source regions 114 of the transistor cells 100 are also electrically connected to the source metallization 124 through the contact structure 126. The source metallization 124, contact structure 126 and interlayer dielectric 128 are not shown in FIG. 1A to provide an unobstructed view of the semiconductor substrate 102.

The gate electrodes 108 are electrically connected to a gate terminal (G) through, e.g., a gate metallization which is not shown in the figures. The gate metallization may be part of a structured power metallization that also includes the source metallization 124. Such a structured power metallization may include a thick power metal layer that comprises Cu, Al, AlCu, AlSiCu, etc., a diffusion barrier and/or adhesion promoter such as Ti and/or TiN and/or W between the thick power metal layer and the interlayer dielectric 128. A drain metallization 130 may be provided at the opposite side of the semiconductor substrate 102 as the source metallization 128.

The neighboring (adjacent) trenches 104 shown in FIG. 1A are ‘active’ trenches in that the semiconductor mesas 111 defined by the active trenches 104 contribute to the main current flow of the semiconductor device. For these neighboring/adjacent active trenches 104, the trenches 104 may have the same dimensions (e.g., depth, width, length) in the entire active area of the device where the main current flow occurs, the active area being the part of the semiconductor substrate 102 that includes the source region 114. The gate electrodes 108 may have the same dimensions (e.g., depth, width, length) in the entire active area of the device. The field electrodes 110 may have the same dimensions (e.g., depth, width, length) in the entire active area of the device. The thickness T_b_ox of the at least one dielectric material 112 between the field electrode 110 and the bottom 132 of the trenches 104 may be uniform in the entire active area of the device. The trench width and therefore the width of the gate electrode 108 may change in some location along the length (y direction in FIGS. 1A and 1B) of the trenches 104, e.g., to accommodate gate contacts outside the active area. There also may be a region along the length (y direction in FIGS. 1A and 1B) of the active trenches 104 without the gate electrode 108 and where the field electrode 110 is contacted outside the active area. The field electrode 110 might extend to the first main surface 106 in this location, for example.

The at least one dielectric material (such as a single dielectric material or a material stack) 112 disposed in the trenches 104 and that separates the gate electrode 108 and the field electrode 110 from one another and from the semiconductor substrate 102 may use the same material throughout, e.g., thermal and/or deposited oxide. In one embodiment, the at least one dielectric material 112 includes any combination of thermal and/or deposited SiO₂ between the gate electrode 108 and the body regions 116. Between the field electrode 110 and the drift region 118, the at least one dielectric material 112 may include any combination of thermal and/or deposited SiO₂ and an oxynitride or nitride may be included (e.g., in a stack). In other embodiments, the at least one dielectric material 112 may include a stack of thermal oxide, HDP (high density plasma) oxide, and deposited oxide from a field oxidation process between the field electrode 110 and the drift region 118 and an oxynitride or nitride may be included (e.g., in a stack). In some embodiments, the at least one dielectric material 112 may include a stack of thermal oxide and HDP oxide between the gate electrode 108 and the field electrode 110. Still other insulative material combinations are considered for the at least one dielectric material 112.

The at least one dielectric material 112 is thicker (T_b_ox>W_f_ox) between the field electrode 110 and the bottom 132 of the trenches 104 than between the field electrode 110 and each sidewall 134 of the trenches 104. Each trench 104 has a uniform width (CD1=CD2) over a depth ‘D_t’ of the trench 104 in the vertical direction (z direction in FIGS. 1A and 1B), or a tapered width (CD1>CD2) that decreases along the depth D_t of the trench 104.

In one embodiment, the at least one dielectric material (such as a single dielectric material or a material stack) 112 is 1.5 to 10 times thicker, e.g., 4 to 10 times thicker, e.g., 2 to 6 times thicker, between the field electrode 110 and the bottom 132 of the trenches 104 than between the field electrode 110 and each sidewall 134 of the trenches 104. For example, the thickness T_b_ox of the at least one dielectric material 112 between the field electrode 110 and the bottom 132 of the trenches 104 may be about 200 nm and the thickness W_f_ox of the at least one dielectric material 112 between the field electrode 110 and each sidewall 134 of the trenches 104 may be about 70 nm. Additional benefit may be gained by further increasing T_b_ox to 300 nm, 400 nm, or greater. For T_b_ox between 200 nm to 400 nm, FOMoss (i.e., Rdson*Qoss) is further reduced by about 10%.

Between the field electrode 110 and the bottom 132 of the trenches 104, the at least one dielectric material 112 may traverse 10% to 67% of the overall trench depth ‘D_t’. For example, the trench depth D_t may be about 870 nm and the thickness T_b_ox of the at least one dielectric material 112 between the field electrode 110 and the bottom 132 of the trenches 104 may be about 200 nm. For D_t of 1000 nm and T_b_ox of 150 nm, the at least one dielectric material 112 traverses 15% of D_t between the field electrode 110 and the bottom 132 of the trenches 104. The overall trench depth D_t is likely proportional to the nominal (breakdown) voltage rating of the device, and a higher % thickness of the at least one dielectric material 112 between the field electrode 110 and the bottom 132 of the trenches 104 relative to D_t yields greater Qoss reduction. For the minimum case, D_t may be 1000 nm, T_b_ox may be 100 nm, and the at least one dielectric material stack 112 may traverse 10% of D_t between the field electrode 110 and the bottom 132 of the trenches 104. For the maximum case, D_t may be 900 nm, T_b_ox may be 600 nm, and the at least one dielectric material 112 may traverse 67% of D_t between the field electrode 110 and the bottom 132 of the trenches 104.

The field electrode 110 may have a thickness ‘T_f’ in the vertical direction (z direction in FIGS. 1A and 1B) that ranges from 100 nm to 1200 nm and between the field electrode 110 and the bottom 132 of the trenches 104, the at least one dielectric material 112 may have a thickness T_b_ox in the vertical direction that ranges from 100 nm to 600 nm. For a nominal (breakdown) voltage rating of 25V, the T_f may be in a range of 150 nm to 400 nm. The T_f value may increase for higher voltage devices and decrease for lower voltage devices. The field plate thickness T_f is a variable that allows for adjustment of the Rdson-breakdown-Qoss trade-off (no field electrode yields the highest Rdson but lowest Qoss for the same breakdown voltage, whereas the tallest field electrode yields the lowest Rdson but highest Qoss).

For nominal voltage ratings up to 40V, T_f may range from 100 nm to 1200 nm, T_b_ox may range from 100 nm to 600 nm, and the T_f/T_b_ox ratio may range from a minimum of 0.17 (100 nm/600 nm) to a maximum of 6 (600 nm/100 nm). For example, T_f may range from 100 nm to 600 nm for a 25V nominal voltage rating and from 100 nm to 1200 nm for a 40V nominal voltage rating. For nominal voltage ratings up to 40V, the thickness ‘T_g’ of the gate electrode 108 in the vertical direction (z direction in FIGS. 1A and 1B) may range from 100 nm to 500 nm and the thickness ‘T_f_ox’ of the at least one dielectric material 112 between the gate electrode 108 and the field electrode 110 may range from 50 nm to 300 nm. The thickness T_f_ox of the at least one dielectric material 112 between the gate electrode 108 and the field electrode 110 may larger or smaller than the thickness T_b_ox of the at least one dielectric material 112 between the field electrode 110 and the bottom 132 of the trenches 104.

Depending on the processing used to form the at least one dielectric material 112, which is described in more detail later herein, each sidewall 134 of the trenches 104 may have a step profile 136 in the vicinity of the bottom 138 of the field electrode 110. The step profile 136 may occur if a thermal oxide liner is used to achieve good oxide interface quality with low number of interface states. The step profile 136 may be avoided by using a SiN liner that remains in the trenches 104. In another embodiment, the trenches 104 have a uniform width (i.e., no step profile 136) over the trench depth D_t.

The field electrodes 110 may terminate at a depth of 33% to 90% of the trench depth D_t, where the depth is measured from the first main surface 106 of the semiconductor substrate 102 and is given by D_t-T_b_ox. For example, the field electrodes 110 may terminate at a depth of about 620 nm while the trenches 104 terminate at a depth of about 870 nm. The depth of the field electrodes 110 helps determine the breakdown voltage rating of the device, and also effects the R*AA-Qoss trade-off. For a 25V nominal voltage rating, the depth of the field electrodes 110 may be in a range of 620 nm+/−150 nm. The trench depth beyond the field electrode termination point is then equivalent to the thickness T_b_ox of the at least one dielectric material 112 between the field electrode 110 and the bottom 132 of the trenches 104. More generally, the field electrodes 110 may terminate at a depth in a range of 300 nm to 900 nm and the trenches 104 may terminate at a depth of 350 nm to 2600 nm.

In FIG. 1B, the trenches 104 vertically terminate in the drift region 118 of the semiconductor device. In one embodiment, the drift region 118 has a doping concentration in a range of 2e16 cm⁻³ to 2e17 cm⁻³. The doping concentration of the drift region 118 depends on the voltage class of the device. Even with some increase in on resistance (Rdson), the reduction in Qoss more than compensates for this increase. For example, Rdson may be 10 to 30% higher but Qoss is 50 to 60% lower. At switching frequencies of 1.5 to 2 MHz, e.g., higher efficiency may be achieved across the load range.

A transition region 140 having a higher average doping concentration than the drift region 118 may be vertically interposed between the drift region 118 and the drain region 120. The drain region 120 has a higher average doping concentration than the transition region 140. The drift region 118, the transition region 140 and the drain region 120 have the same conductivity type (e.g., n-type for an n-channel device and p-type for a p-channel device).

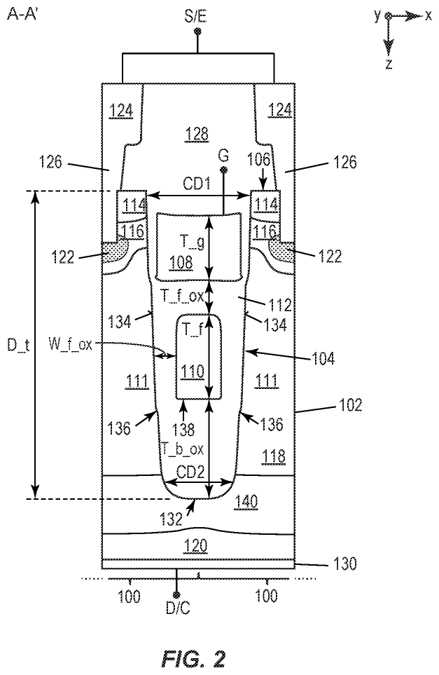

FIG. 2 illustrates a cross-sectional view of the semiconductor device take along the line labelled A-A′ in FIG. 1A, according to another embodiment. In FIG. 2, the trenches 104 vertically extend through the drift region 118 and into the more highly doped transition region 140. The trenches 104 terminate before reaching the drain region 120 in FIG. 2. A more highly doped transition region 140 results in lower hot carrier injection during avalanche but increases Qoss. For some devices, a lower doped transition region 140 may be beneficial. If the field electrode 110 does not extend into the transition region 140, e.g., as shown in FIG. 2, Qoss will not increase as much.

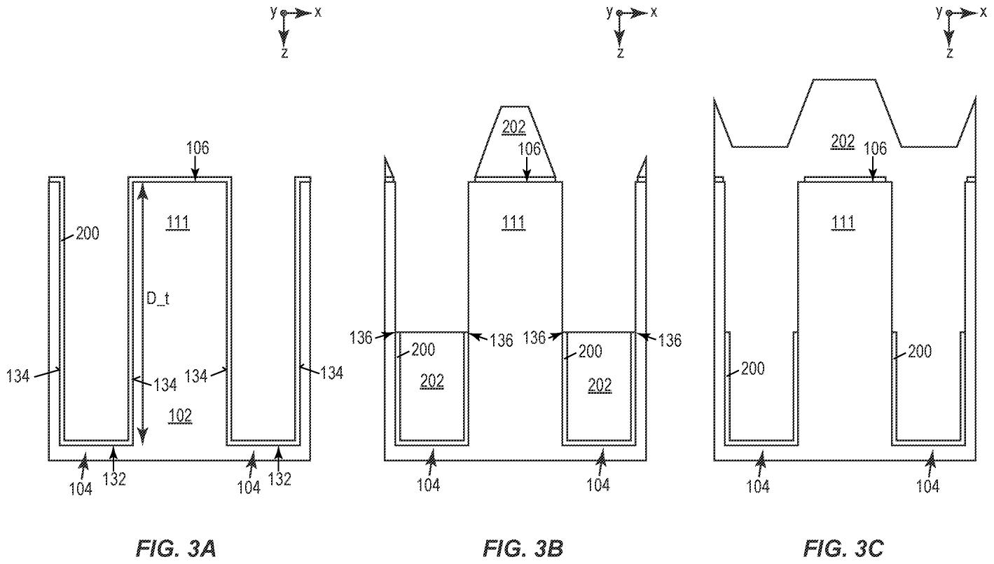

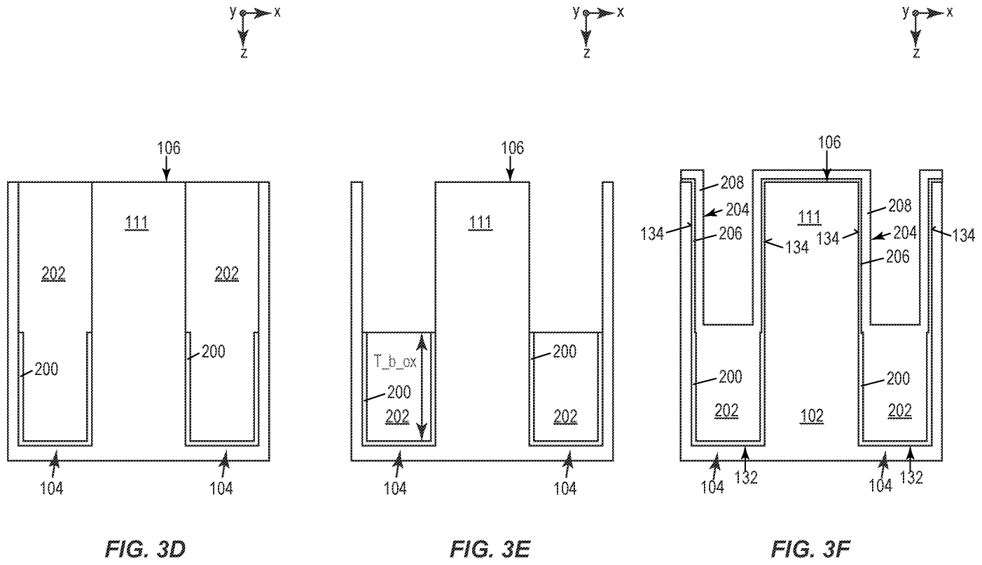

FIGS. 3A through 3F illustrate a partial cross-sectional view between two (2) adjacent trenches 104 of the semiconductor device during different stages of production, according to an embodiment.

FIG. 3A shows the semiconductor substrate 102 after the trenches 104 are etched into the first main surface 106 of the semiconductor substrate 102 to a depth D_t and a liner 200 is formed on each sidewall 134 and the bottom 132 of the trenches 104. The liner 200 may be a single layer (e.g., thermal oxide or SiN) or a layer stack (e.g., thermal oxide and SiN).

FIG. 3B shows the semiconductor substrate 102 after the trenches 104 are at least partly filled with a high-density-plasma chemical vapour deposited (HDP-CVD) oxide 202. High-density plasma chemical vapor deposition is a form of plasma-enhanced chemical vapor deposition (PECVD) that uses an inductively coupled plasma source that provides a high plasma density.

The HDP-CVD oxide 202 grows thick on planar surfaces and the trench bottom 132, but thin on the sidewalls 134 because of a sputtered component. To avoid forming voids in the HDP-CVD oxide 202, an iterative process may be employed as shown in FIGS. 3B and 3C and according to which the trenches 104 are at least partly filed with the HDP-CVD oxide 202 in two or more iterations of an HDP-CVD process followed by a wet etch process before the next iteration.

In FIG. 3B, the sidewall HDP-CVD oxide is removed by a wet etch process. If the liner 200 comprises just a single layer of thermal oxide or a thermal oxide outer layer, the thermal oxide is also removed by the wet etch process as shown in FIG. 3B. If the liner 200 comprises just a single layer of SiN or a SiN outer layer with a thermal oxide inner layer, the liner 200 would not be affected by the wet etching.

In FIG. 3C, the HDP-CVD process and wet etch process are repeated at least once to completely fill the trenches 104 with the HDP-CVD oxide 202. In some embodiments, the HDP-CVD oxide 202 could instead be formed with a single HDP-CVD/etch step, but the HDP-CVD process may be limited by the trench aspect ratio.

FIG. 3D shows the semiconductor substrate 102 after the HDP-CVD oxide 202 and the liner 200 are removed from the first main surface 106 of the semiconductor substrate 102 by a planarization process. For example, the HDP-CVD oxide 202 and the liner 200 may be removed from the first main surface 106 of the semiconductor substrate 102 by CMP (chemical-mechanical polishing).

FIG. 3E shows the semiconductor substrate 102 after removing the HDP-CVD oxide 202 from the upper part of the trenches 104. In one embodiment, the HDP-CVD oxide 202 is removed from the upper part of the trenches 104 by a by wet etch process to avoid rounding of the corners of the trenches 104. If the liner 200 comprises just a single layer of thermal oxide or a thermal oxide outer layer, the sidewall step profile 136 previously described herein in connection with FIG. 1A may be present. The step profile 136 may be minimized by making the thermal oxide layer thinner, which improves field electrode shielding.

The liner 200 could instead comprise just a single layer of SiN or a SiN outer layer with a thermal oxide inner layer. Such a liner composition would avoid the step profile 136 along the trench sidewalls 134. Also, the liner 200 may remain in the upper and lower part of the trenches 104 since the wet etch process would not attack SiN. The SiN liner could be removed before forming the field plate/gate electrode stack, using a separate SiN liner removal process. The SiN liner instead could permanently remain on each sidewall 134 in the upper part of the trenches 104 and form part of the at least one dielectric material 112. A pad (thermal) oxide could be formed under the nitride to form a liner stack structure.

In each case, the recess etch of the HDP-CVD oxide 202 from the upper part of the trenches 104 in FIG. 3E defines the thickness T_b_ox of the at least one dielectric material 112 between the field electrode 110 and the bottom 132 of the trenches 104. T_b_ox may be in a range of 100 nm to 600 nm. The removal of the HDP-CVD oxide 202 from the upper part of the trenches 104 may involve a bulk etch followed by a controlled wet etch to yield a well-controlled trench bottom oxide height or thickness T_b_ox.

FIG. 3F shows the semiconductor substrate 102 after lining each exposed trench sidewall 134 with an electrically insulating material 204 in the upper part of the trenches 104. For example, the electrically insulating material 204 may include a thinner thermal oxide (e.g., ˜5 nm) 206 covered by a thicker oxide (e.g., 30 nm) 208 formed by ALD (atomic layer deposition) and/or TEOS (tetraethoxysilane). For example, the electrically insulating material 204 may include about 30 nm of thermal oxide and about 50 nm of deposited oxide (e.g., TEOS). The electrically insulating material 204 instead may be formed using just ALD for better control.

The method proceeds with standard trench processing to form the gate electrode 108 and the field electrode 110 in the trenches 104. This may include polysilicon deposition, followed by a polysilicon recess to define the field electrodes 110. An oxide component of the at least one dielectric material 112 is then deposited on the field electrodes 110, and the gate electrodes 108 are formed on the field oxide.

Although the present disclosure is not so limited, the following numbered examples demonstrate one or more aspects of the disclosure.

Example 1. A semiconductor device, comprising: a semiconductor substrate; and a plurality of transistor cells formed in the semiconductor substrate and electrically coupled in parallel to form a power transistor, wherein each trench of the plurality of transistor cells comprises a plurality of trenches extending in a vertical direction from a first main surface of the semiconductor substrate into the semiconductor substrate, wherein the plurality of trenches comprises: a gate electrode; a field electrode below the gate electrode; and at least one dielectric material separating the gate electrode and the field electrode from one another and from the semiconductor substrate, wherein the at least one dielectric material is thicker between the field electrode and a bottom of the trenches than between the field electrode and each sidewall of the trenches, wherein each trench has a tapered width that decreases over a depth of the trench in the vertical direction.

Example 2. The semiconductor device of example 1, wherein the at least one dielectric material is 1.5 to 10 times thicker between the field electrode and the bottom of the trenches than between the field electrode and each sidewall of the trenches.

Example 3. The semiconductor device of example 1 or 2, wherein between the field electrode and the bottom of the trenches, the at least one dielectric material traverses 10% to 67% of the trench depth.

Example 4. The semiconductor device of any of examples 1 through 3, wherein the field electrode has a thickness in the vertical direction that ranges from 100 nm to 600 nm, and wherein between the field electrode and the bottom of the trenches, the at least one dielectric material has a thickness in the vertical direction that ranges from 100 nm to 600 nm.

Example 5. The semiconductor device of any of examples 1 through 4, wherein each sidewall of the trenches has a step profile in a vicinity of a bottom of the field electrode.

Example 6. The semiconductor device of any of examples 1 through 4, wherein the trench has a uniform width over the trench depth.

Example 7. The semiconductor device of any of examples 1 through 6, wherein in the vertical direction, the trenches terminate in a drift region of the semiconductor device, and wherein the drift region has a doping concentration in a range of 2e16 cm⁻³ to 2e17 cm⁻³.

Example 8. The semiconductor device of any of examples 1 through 7, wherein in the vertical direction, the trenches extend through a drift region of the semiconductor device and into a transition region that has a higher average doping concentration than the drift region, wherein the transition region is vertically interposed between the drift region and a substrate region that has a higher average doping concentration than the transition region, and wherein the drift region, the transition region and the substrate region have a same conductivity type.

Example 9. The semiconductor device of any of examples 1 through 8, wherein the field electrode terminates at a depth of 33% to 90% of the trench depth.

Example 10. The semiconductor device of any of examples 1 through 9, wherein the power transistor has a nominal voltage rating of 40V or less.

Example 11. The semiconductor device of any of examples 1 through 10, wherein the field electrode has a thickness in the vertical direction that ranges from 100 nm to 1200 nm, and wherein the gate electrode has a thickness in the vertical direction that ranges from 100 nm to 500 nm.

Example 12. The semiconductor device of any of examples 1 through 11, wherein between the field electrode and the bottom of the trenches, the at least one dielectric material has a thickness in the vertical direction that ranges from 100 nm to 600 nm, and wherein between the gate electrode and the field electrode, the at least one dielectric material has a thickness in the vertical direction that ranges from 50 nm to 300 nm.

Example 13. The semiconductor device of any of examples 1 through 12, wherein the at least one dielectric material is 4 to 10 times thicker between the field electrode and the bottom of the trenches than between the field electrode and each sidewall of the trenches.

Example 14. The semiconductor device of any of examples 1 through 13, wherein the semiconductor device has a nominal voltage rating of 25V or less, wherein the field electrode has a thickness in the vertical direction that ranges from 100 nm to 600 nm, and wherein between the field electrode and the bottom of the trench, the at least one dielectric material has a thickness in the vertical direction that ranges from 100 nm to 600 nm.

Example 15. The semiconductor device of any of examples 1 through 13, wherein the semiconductor device has a nominal voltage rating of 40V or less, wherein the field electrode has a thickness in the vertical direction that ranges from 100 nm to 1200 nm, and wherein between the field electrode and the bottom of the trench, the at least one dielectric material has a thickness in the vertical direction that ranges from 100 nm to 600 nm.

Example 16. A method of producing a semiconductor device, the method comprising: forming a plurality of transistor cells in a semiconductor substrate; and electrically coupling the plurality of transistor cells in parallel to form a power transistor, wherein forming the plurality of transistor cells comprises: etching a plurality of trenches into a first main surface of the semiconductor substrate and extending in a vertical direction into the semiconductor substrate; and in each trench, forming a gate electrode, a field electrode below the gate electrode, and at least one dielectric material that separates the gate electrode and the field electrode from one another and from the semiconductor substrate, wherein the at least one dielectric material is thicker between the field electrode and a bottom of the trenches than between the field electrode and each sidewall of the trenches, wherein each trench has a tapered width that decreases over a depth of the trench in the vertical direction.

Example 17. The method of example 16, wherein forming the at least one dielectric material comprises: forming a liner on each sidewall and the bottom of the trenches; after forming the liner, at least partly filling the trenches with a high-density-plasma chemical vapour deposited (HDP-CVD) oxide; and removing the HDP-CVD oxide from an upper part of the trenches.

Example 18. The method of claim 16, wherein forming the dielectric material or material stack comprises: forming a liner on each sidewall and the bottom of the trenches; after forming the liner, fully filling the trenches with a high-density-plasma chemical vapour deposited (HDP-CVD) oxide; and removing the HDP-CVD oxide from an upper part of the trenches.

Example 19. The method of example 18, wherein the liner is a thermal oxide, and wherein the thermal oxide and the HDP-CVD oxide are removed from the upper part of the trenches by a wet etch process.

Example 20. The method of example 19, further comprising: after removing the thermal oxide and the HDP-CVD oxide from the upper part of the trenches, lining each sidewall with an electrically insulating material in the upper part of the trenches.

Example 21. The method of example 18, wherein the liner is silicon nitride.

Example 22. The method of example 21, further comprising: after removing the HDP-CVD oxide from the upper part of the trenches, removing the silicon nitride from the upper part of the trenches.

Example 23. The method of example 21, wherein the silicon nitride liner permanently remains on each sidewall in the upper part of the trenches.

Example 24. The method of example 18, wherein the liner comprises a thermal oxide covered by silicon nitride.

Example 25. The method of example 18, wherein fully filling the trenches with the HDP-CVD oxide comprises two or more iterations of an HDP-CVD process followed by a wet etch process before the next iteration.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a semiconductor substrate; and
a plurality of transistor cells formed in the semiconductor substrate and electrically coupled in parallel to form a power transistor,
wherein the plurality of transistor cells comprises a plurality of trenches extending in a vertical direction from a first main surface of the semiconductor substrate into the semiconductor substrate,
wherein each transistor of the plurality of trenches comprises:
a gate electrode;
a field electrode below the gate electrode; and
at least one dielectric material separating the gate electrode and the field electrode from one another and from the semiconductor substrate,
wherein the at least one dielectric material is thicker between the field electrode and a bottom of the trenches than between the field electrode and each sidewall of the trenches,
wherein each trench has a tapered width that decreases over a depth of the trench in the vertical direction.

2. The semiconductor device of claim 1, wherein the at least one dielectric material is 1.5 to 10 times thicker between the field electrode and the bottom of the trenches than between the field electrode and each sidewall of the trenches.

3. The semiconductor device of claim 2, wherein the at least one dielectric material is 4 to 10 times thicker between the field electrode and the bottom of the trenches than between the field electrode and each sidewall of the trenches.

4. The semiconductor device of claim 1, wherein between the field electrode and the bottom of the trenches, the at least one dielectric material traverses 10% to 67% of the trench depth.

5. The semiconductor device of claim 1, wherein the field electrode has a thickness in the vertical direction that ranges from 100 nm to 600 nm, and wherein between the field electrode and the bottom of the trenches, the at least one dielectric material has a thickness in the vertical direction that ranges from 100 nm to 600 nm.

6. The semiconductor device of claim 1, wherein each sidewall of the trenches has a step profile in a vicinity of a bottom of the field electrode.

7. The semiconductor device of claim 1, wherein in the vertical direction, the trenches terminate in a drift region of the semiconductor device, and wherein the drift region has a doping concentration in a range of 2e16 cm⁻³ to 2e17 cm⁻³.

8. The semiconductor device of claim 1, wherein in the vertical direction, the trenches extend through a drift region of the semiconductor device and into a transition region that has a higher average doping concentration than the drift region, wherein the transition region is vertically interposed between the drift region and a substrate region that has a higher average doping concentration than the transition region, and wherein the drift region, the transition region and the substrate region have a same conductivity type.

9. The semiconductor device of claim 1, wherein the field electrode terminates at a depth of 33% to 90% of the trench depth.

10. The semiconductor device of claim 1, wherein the power transistor has a nominal voltage rating of 40V or less.

11. The semiconductor device of claim 1, wherein the field electrode has a thickness in the vertical direction that ranges from 100 nm to 1200 nm, and wherein the gate electrode has a thickness in the vertical direction that ranges from 100 nm to 500 nm.

12. The semiconductor device of claim 1, wherein between the field electrode and the bottom of the trenches, the at least one dielectric material has a thickness in the vertical direction that ranges from 100 nm to 600 nm, and wherein between the gate electrode and the field electrode, the at least one dielectric material has a thickness in the vertical direction that ranges from 50 nm to 300 nm.

13. The semiconductor device of claim 1, wherein the semiconductor device has a nominal voltage rating of 25V or less, wherein the field electrode has a thickness in the vertical direction that ranges from 100 nm to 600 nm, and wherein between the field electrode and the bottom of the trench, the at least one dielectric material has a thickness in the vertical direction that ranges from 100 nm to 600 nm.

14. The semiconductor device of claim 1, wherein the semiconductor device has a nominal voltage rating of 40V or less, wherein the field electrode has a thickness in the vertical direction that ranges from 100 nm to 1200 nm, and wherein between the field electrode and the bottom of the trench, the at least one dielectric material has a thickness in the vertical direction that ranges from 100 nm to 600 nm.

15. A method of producing a semiconductor device, the method comprising:
forming a plurality of transistor cells in a semiconductor substrate; and
electrically coupling the plurality of transistor cells in parallel to form a power transistor, wherein forming the plurality of transistor cells comprises:
etching a plurality of trenches into a first main surface of the semiconductor substrate and extending in a vertical direction into the semiconductor substrate; and
in each trench, forming a gate electrode, a field electrode below the gate electrode, and at least one dielectric material that separates the gate electrode and the field electrode from one another and from the semiconductor substrate,
wherein the at least one dielectric material is thicker between the field electrode and a bottom of the trenches than between the field electrode and each sidewall of the trenches,
wherein each trench has a tapered width that decreases over a depth of the trench in the vertical direction.

16. The method of claim 15, wherein forming the at least one dielectric material comprises:
forming a liner on each sidewall and the bottom of the trenches;
after forming the liner, at least partly filling the trenches with a high-density-plasma chemical vapour deposited (HDP-CVD) oxide; and
removing the HDP-CVD oxide from an upper part of the trenches.

17. The method of claim 15, wherein forming the at least one dielectric material comprises:
forming a liner on each sidewall and the bottom of the trenches;
after forming the liner, fully filling the trenches with a high-density-plasma chemical vapour deposited (HDP-CVD) oxide; and
removing the HDP-CVD oxide from an upper part of the trenches.

18. The method of claim 17, wherein the liner is a thermal oxide, and wherein the thermal oxide and the HDP-CVD oxide are removed from the upper part of the trenches by a wet etch process.

19. The method of claim 18, further comprising:
after removing the thermal oxide and the HDP-CVD oxide from the upper part of the trenches, lining each sidewall with an electrically insulating material in the upper part of the trenches.

20. The method of claim 17, wherein the liner is silicon nitride.

21. The method of claim 20, further comprising:
after removing the HDP-CVD oxide from the upper part of the trenches, removing the silicon nitride from the upper part of the trenches.

22. The method of claim 20, wherein the silicon nitride liner permanently remains on each sidewall in the upper part of the trenches.

23. The method of claim 17, wherein the liner comprises a thermal oxide covered by silicon nitride.

24. The method of claim 17, wherein fully filling the trenches with the HDP-CVD oxide comprises two or more iterations of an HDP-CVD process followed by a wet etch process before the next iteration.
